(19) United States
(12) Patent Application Publication
(10) Pub. No.: US 2024/0268151 A1
(43) Pub. Date: Aug. 8, 2024

(54) DISPLAY DEVICE AND MANUFACTURING METHOD THEREOF

(71) Applicant: Samsung Display Co., LTD., Yongin-si (KR)

(72) Inventors: Jong Oh SEO, Yongin-si (KR); Jong Jun BAEK, Yongin-si (KR)

(73) Assignee: Samsung Display Co., LTD., Yongin-si (KR)

(21) Appl. No.: 18/515,270

(22) Filed: Nov. 21, 2023

(30) Foreign Application Priority Data
Feb. 7, 2023 (KR) 10-2023-0016195

(51) Int. Cl. H10K 59/121; H10K 59/12

(52) U.S. Cl. CPC H10K 59/1213; H10K 59/1201

(57) ABSTRACT

A display device includes a light-emitting device; a first transistor that outputs a driving current applied to the light-emitting device; a second transistor that transmits a data voltage to a first electrode of the first transistor; and a third transistor electrically connected to a second electrode and a gate electrode of the first transistor, a first semiconductor layer of the first transistor includes fluorine ions, a third semiconductor layer of the third transistor includes a third lower doping layer and a third upper doping layer sequentially disposed, a concentration of phosphorus ions of the third lower doping layer is greater than a concentration of phosphorus ions of the third upper doping layer, and a concentration of boron ions of the third upper doping layer is greater than a concentration of boron ions of the third lower doping layer.

### CROSS-REFERENCE TO RELATED APPLICATION(S)

This application claims priority to and benefits of Korean Patent Application No. 10-2023-0016195 under 325 U.S.C. § 119 filed in the Korean Intellectual Property Office on Feb. 7, 2023, the entire contents of which are incorporated herein by reference.

### BACKGROUND

### 1. Technical Field

The disclosure relates to a display device and a manufacturing method thereof.

### 2. Description of the Related Art

A display device displays images on a screen and may include a liquid crystal display (LCD) and an organic light emitting diode (OLED) display. The display device is used for various electronic devices such as a portable phone, a GPS, a digital camera, an electronic book, a portable game device, or various terminals.

An organic light emitting device may include two electrodes and an organic emission layer disposed therebetween, and electrons injected from one electrode are combined with holes injected from the other electrode on an organic emission layer to form excitons. The excitons transit to a ground state from an excited state to output energy and emit light.

The organic light emitting device may include a plurality of pixels including an organic light emitting diode that is a self-light-emitting device, and a plurality of transistors and at least one capacitor for driving the organic light emitting diode are formed on respective pixels.

Regarding the organic light emitting device, a surface of a semiconductor layer of a driving transistor for controlling a driving current flowing to an organic light emitting diode may be degraded by a hysteresis phenomenon to generate afterimages.

Afterimages may be minimized by doping fluorine ions to the semiconductor layer and processing a surface of the semiconductor layer according to a laser heat treatment before crystallizing the semiconductor layer. However, a leakage current (Ioff) may increase.

The above information disclosed in this background section is only for enhancement of understanding of the background of the disclosure, and therefore it may contain information that does not form the prior art that may already be known to a person of ordinary skill in the art.

### SUMMARY

The disclosure has been made in an effort to provide a display device for removing afterimages and minimizing a leakage current, and a manufacturing method thereof.

An embodiment provides a display device that may include a light-emitting device; a first transistor that outputs a driving current applied to the light-emitting device; a second transistor that transmits a data voltage to a first electrode of the first transistor; and a third transistor electrically connected to a second electrode and a gate electrode of the first transistor, wherein a first semiconductor layer of the first transistor may include fluorine ions, a third semiconductor layer of the third transistor may include a third lower doping layer and a third upper doping layer sequentially disposed, a concentration of phosphorus ions of the third lower doping layer is greater than a concentration of phosphorus ions of the third upper doping layer, and a concentration of boron ions of the third upper doping layer is greater than a concentration of boron ions of the third lower doping layer.

A maximum point of a concentration of phosphorus ions of the third semiconductor layer may be disposed on the third lower doping layer.

The display device may further include a fourth transistor that transmits an initialization voltage to a gate electrode of the first transistor, wherein a fourth semiconductor layer of the fourth transistor may include a fourth lower doping layer and a fourth upper doping layer sequentially disposed, a concentration of phosphorus ions of the fourth lower doping layer may be greater than a concentration of phosphorus ions of the fourth upper doping layer, and a concentration of boron ions of the fourth upper doping layer may be greater than a concentration of boron ions of the fourth lower doping layer.

A maximum point of the concentration of phosphorus ions of the fourth semiconductor layer may be disposed on the fourth lower doping layer.

The display device may further include a fifth transistor that transmits a driving voltage to a first electrode of the first transistor; a sixth transistor that transmits the driving voltage to the light-emitting device from the fifth transistor; and a seventh transistor that electrically connects a first electrode of the fourth transistor to a first electrode of the sixth transistor.

A fifth semiconductor layer of the fifth transistor may include a fifth lower doping layer and a fifth upper doping layer sequentially disposed, a concentration of phosphorus ions of the fifth lower doping layer may be greater than a concentration of phosphorus ions of the fifth upper doping layer, a concentration of boron ions of the fifth upper doping layer may be greater than a concentration of boron ions of the fifth lower doping layer, a sixth semiconductor layer of the sixth transistor may include a sixth lower doping layer and a sixth upper doping layer sequentially disposed, a concentration of phosphorus ions of the sixth lower doping layer may be greater than a concentration of phosphorus ions of the sixth upper doping layer, a concentration of boron ions of the sixth upper doping layer may be greater than a concentration of boron ions of the sixth lower doping layer, a seventh semiconductor layer of the seventh transistor may include a seventh lower doping layer and a seventh upper doping layer sequentially disposed, a concentration of phosphorus ions of the seventh lower doping layer may be greater than a concentration of phosphorus ions of the seventh upper doping layer, and a concentration of boron ions of the seventh upper doping layer may be greater than a concentration of boron ions of the seventh lower doping layer.

A fifth semiconductor layer of the fifth transistor may include boron ions, a sixth semiconductor layer of the sixth transistor may include boron ions, and a seventh semiconductor layer of the seventh transistor may include boron ions.

The third transistor and the fourth transistor may be driven at a low frequency substantially equal to or less than about 60 Hz.

An embodiment provides a method for manufacturing a display device that may include forming a semiconductor layer on a substrate; forming a first semiconductor layer of a first transistor that outputs a driving current applied to a light-emitting device by doping fluorine ions in a first region of the semiconductor layer; forming a third semiconductor layer of a third transistor electrically connected to a second electrode and a gate electrode of the first transistor by doping phosphorus ions to a lower portion of a second region of the semiconductor layer; crystallizing the first semiconductor layer and the third semiconductor layer; and doping boron ions on an upper portion of the third semiconductor layer.

The third semiconductor layer may include a third lower doping layer and a third upper doping layer sequentially disposed, a concentration of phosphorus ions of the third lower doping layer may be greater than a concentration of phosphorus ions of the third upper doping layer, and a concentration of boron ions of the third upper doping layer may be greater than a concentration of boron ions of the third lower doping layer.

A fourth semiconductor layer of a fourth transistor that transmits an initialization voltage to a gate electrode of the first transistor may be formed in the second region, the fourth semiconductor layer may include a fourth lower doping layer and a fourth upper doping layer sequentially disposed, a concentration of phosphorus ions of the fourth lower doping layer may be greater than a concentration of phosphorus ions of the fourth upper doping layer, and a concentration of boron ions of the fourth upper doping layer may be greater than a concentration of boron ions of the fourth lower doping layer.

The first semiconductor layer may be crystallized after the fluorine ions are doped on the first semiconductor layer.

The third semiconductor layer and the fourth semiconductor layer may be crystallized after the phosphorus ions are doped on the third semiconductor layer and the fourth semiconductor layer.

The boron ions may be doped on the third semiconductor layer and the fourth semiconductor layer after the third semiconductor layer and the fourth semiconductor layer are crystallized.

An acceleration voltage applied to the phosphorus ions may be greater than an acceleration voltage applied to the boron ions.

The fluorine ions may be accelerated in a range of about 3 to about 15 KeV, and a doping concentration of the fluorine ions may be in a range of about 1×10¹¹ to about 1×10¹² cm⁻².

The phosphorus ions may be accelerated in a range of about 10 to about 40 KeV, and a doping concentration of the phosphorus ions may be in a range of about 1×10¹¹ to about 1×10¹² cm⁻².

The boron ions may be accelerated in a range of about 3 to about 15 KeV, and a doping concentration of the boron ions may be in a range of about 1×10¹¹ to about 1×10¹² cm⁻².

An embodiment provides a method for manufacturing a display device that may include forming a semiconductor layer on a substrate; forming a first semiconductor layer by doping fluorine ions in a first region of the semiconductor layer by a first mask, and blocking the doping of fluorine ions in a second region of the semiconductor layer; forming a third semiconductor layer and a fourth semiconductor layer by doping phosphorus ions in a second region of the semiconductor layer by a second mask, and blocking the doping of phosphorus ions in a first region of the semiconductor layer; crystallizing the first semiconductor layer, the third semiconductor layer, and the fourth semiconductor layer; and doping boron ions on the third semiconductor layer and the fourth semiconductor layer by a third mask, and blocking the doping of boron ions on the first semiconductor layer, wherein an acceleration voltage applied to the phosphorus ions is greater than an acceleration voltage applied to the boron ions.

Fluorine ions may be formed on an upper portion of the first semiconductor layer, and a maximum point of a concentration of phosphorus ions of the third semiconductor layer may be disposed on a lower portion of the third semiconductor layer, and a maximum point of a concentration of phosphorus ions of the fourth semiconductor layer may be disposed on a lower portion of the fourth semiconductor layer.

According to embodiments, the semiconductor layer of the driving transistor T1 may include the fluorine ions to remove the afterimage, the concentration of the phosphorus ions of the lower doping layers of the semiconductor layer of the compensation transistor T3 and the semiconductor layer of the initialization transistor T4 is higher than the concentration of the phosphorus ion of the upper doping layer, and the concentration of the boron ions of the lower doping layers of the semiconductor layer of the compensation transistor T3 and the semiconductor layer of the initialization transistor T4 is lower than the concentration of the boron ions of the upper doping layer, thereby minimizing the leakage current. Therefore, the afterimages may be removed and the leakage current may be minimized.

Further, in case that performing a low frequency driving of substantially equal to or less than 60 Hz for the purpose of reducing power consumption, flickers such as screen shivering or blinking may be generated by the leakage current, but an embodiment may suppress the generation of flicker by minimizing the leakage current in case that a low frequency is progressed.

### BRIEF DESCRIPTION OF THE DRAWINGS

The above and other advantages of the disclosure will become readily apparent by reference to the following detailed description when considered in conjunction with the accompanying drawings wherein:

FIG. 1 shows a schematic diagram of an equivalent circuit diagram of a pixel of a display device according to an embodiment.

FIG. 2 shows a schematic cross-sectional view of a first transistor, a second transistor, and a sixth transistor of a display device of FIG. 1.

FIG. 3 shows a schematic cross-sectional view of a third transistor, a fourth transistor, a fifth transistor, and a seventh transistor of a display device of FIG. 1.

FIG. 4 shows an enlarged schematic cross-sectional view of semiconductor layers of a first transistor, a third transistor, and a fourth transistor of a display device of FIG. 1.

FIG. 5 shows a combined state at an interface between a first upper doping layer of a first semiconductor layer of a first transistor and a first gate insulating layer of FIG. 1.

FIG. 6 shows a graph of ion concentrations with respect to depth of a third semiconductor layer of a third transistor or a fourth semiconductor layer of a fourth transistor of FIG. 4.

FIG. 7 shows enlarged schematic cross-sectional views of semiconductor layers of a second transistor, a fifth transistor, a sixth transistor, and a seventh transistor of a display device of FIG. 1.

FIG. 8 to FIG. 10 show sequential schematic cross-sectional views of a method for manufacturing a display device according to an embodiment, showing enlarged schematic cross-sectional views of a first transistor, a second transistor, and a fourth transistor of a display device of FIG. 1.

### DETAILED DESCRIPTION OF THE EMBODIMENTS

The disclosure will be described more fully hereinafter with reference to the accompanying drawings, in which embodiments are shown. As those skilled in the art would realize, the described embodiments may be modified in various different ways, all without departing from the spirit or scope of the disclosure.

Parts that are irrelevant to the description may be omitted to clearly describe the disclosure, and the same elements will be designated by the same reference numerals throughout the specification.

Parts that are irrelevant to the description may be omitted to clearly describe the disclosure, and like reference numerals designate like elements throughout the specification. The thickness of layers, films, panels, regions, etc., are enlarged for clarity. The thicknesses of some layers and areas are exaggerated.

In the disclosure, it will be understood that when an element or layer is referred to as being “on”, “connected to” or “coupled to” another element or layer, it can be directly on, connected or coupled to the other element or layer or intervening elements or layers may be present.

It will be understood that the terms “connected to” or “coupled to” may include a physical or electrical connection or coupling.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means disposed on or below the object portion, and does not necessarily mean disposed on the upper side of the object portion based on a gravitational direction.

The term “overlap” or “overlapped” means that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

Unless explicitly described to the contrary, the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the disclosure.

The phrase “in a plan view” means viewing a target portion from the top, and the phrase “in a cross-sectional view” means viewing a cross-section formed by perpendicularly cutting a target portion from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

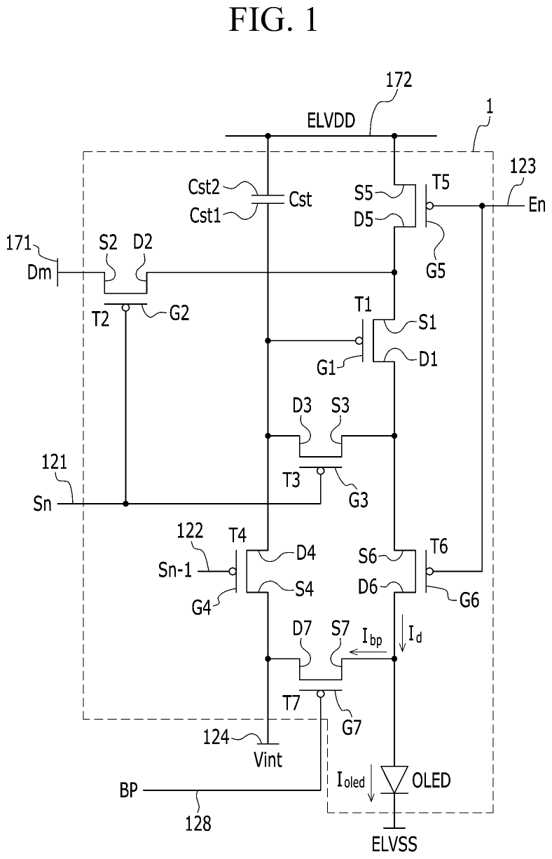

A display device according to an embodiment will now be described with reference to FIG. 1 to FIG. 7.

FIG. 1 shows a schematic diagram of an equivalent circuit diagram of a pixel of a display device according to an embodiment.

The pixel of FIG. 1 will illustrate a pixel included in an n-th pixel row in case that pixels are formed in the display area of the display device.

As shown in FIG. 1, the pixel 1 of the display device may include signal lines 121, 122, 123, 124, 128, 171, and 172, transistors T1, T2, T3, T4, T5, T6, and T7 connected to the signal lines, a storage capacitor Cst, and a light-emitting device. Here, the light-emitting device may include an organic light emitting diode OLED.

The transistors may include a first transistor T1 (also referred to as a driving transistor), a second transistor T2 (also referred to as a switching transistor), a third transistor T3 (also referred to as a compensation transistor), a fourth transistor T4 (also referred to as an initialization transistor), a fifth transistor T5 (also referred to as an operation control transistor), a sixth transistor T6 (also referred to as an emission control transistor), and a seventh transistor (also referred to as a bypass transistor).

The signal lines may include a scan line 121 for transmitting a scan signal Sn, a previous scan line 122 for transmitting a previous scan signal Sn-1 to the fourth transistor T4, an emission control line 123 for transmitting an emission control signal En to the fifth transistor T5 and the sixth transistor T6, an initialization voltage line 124 for transmitting an initialization voltage Vint for initializing the first transistor T1, a bypass line 128 for transmitting a bypass signal BP to the seventh transistor T7, a data line 171 intersecting the scan line 121 and transmitting a data signal Dm, and a driving voltage line 172 for transmitting a driving voltage ELVDD.

A gate electrode G1 of the first transistor T1 is connected to a first end Cst1 of the storage capacitor Cst, a first electrode, that is a source electrode S1, of the first transistor T1 passes through the fifth transistor T5 and is connected to the driving voltage line 172, a second electrode, that is a drain electrode D1, of the first transistor T1 passes through the sixth transistor T6 and is electrically connected to an anode of the organic light emitting diode OLED. The source electrode S1 of the first transistor T1 passes through the second transistor T2 and is connected to the data line 171, and the drain electrode D1 of the first transistor T1 passes through the third transistor T3 and is connected to the driving voltage line 172. The first transistor T1 receives the data signal Dm from the data line 171 and outputs a driving current Id to the organic light emitting diode OLED according to a switching operation of the second transistor T2.

A gate electrode G2 of the second transistor T2 is connected to the scan line 121, a source electrode S2 of the second transistor T2 is connected to the data line 171, and a drain electrode D2 of the second transistor T2 is connected to the source electrode S1 of the first transistor T1, passes through the fifth transistor T5, and is connected to the driving voltage line 172. The second transistor T2 is turned on by the scan signal Sn received through the scan line 121 and transmits the data signal Dm transmitted through the data line 171 to the source electrode of the first transistor T1 to thus perform a switching operation.

A gate electrode G3 of the third transistor T3 is connected to the scan line 121, a source electrode S3 of the third transistor T3 is connected to the drain electrode D1 of the first transistor T1, passes through the sixth transistor T6, and is connected to the anode of the organic light emitting diode OLED, and a drain electrode D3 of the third transistor T3 is connected to the first end Cst1 of the storage capacitor Cst, a drain electrode D4 of the fourth transistor T4, and a gate electrode G1 of the first transistor T1. The third transistor T3 is turned on by the scan signal Sn received through the scan line 121 to connect the gate electrode G1 and the drain electrode D1 of the first transistor T1 and diode-connect the first transistor T1.

A gate electrode G4 of the fourth transistor T4 is connected to the previous scan line 122, a source electrode S4 of the fourth transistor T4 is connected to the initialization voltage line 124, a drain electrode D4 of the fourth transistor T4 is connected to the first end Cst1 of the storage capacitor Cst, the drain electrode D3 of the third transistor T3, the gate electrode G1 of the first transistor T1. The fourth transistor T4 is turned on by the previous scan signal Sn-1 received through the previous scan line 122 and transmits the initialization voltage Vint to the gate electrode G1 of the first transistor T1 to initialize a voltage at the gate electrode G1 of the first transistor T1, thereby performing an initialization operation.

A gate electrode G5 of the fifth transistor T5 is connected to the emission control line 123, a source electrode S5 of the fifth transistor T5 is connected to the driving voltage line 172, and a drain electrode D5 of the fifth transistor T5 is connected to the source electrode S1 of the first transistor T1 and the drain electrode D2 of the second transistor T2.

A gate electrode G6 of the sixth transistor T6 is connected to the emission control line 123, a source electrode S6 of the sixth transistor T6 is connected to the drain electrode D1 of the first transistor T1 and the source electrode S3 of the third transistor T3, and a drain electrode D6 of the sixth transistor T6 is electrically connected to the anode of the organic light emitting diode OLED. The fifth transistor T5 and the sixth transistor T6 are turned on by the emission control signal En received through the emission control line 123 so the driving voltage ELVDD is transmitted to the organic light emitting diode OLED and the emission current Ioled flows to the organic light emitting diode OLED.

A gate electrode G7 of the seventh transistor T7 is connected to the bypass line 128, a source electrode S7 of the seventh transistor T7 is connected to the drain electrode D6 of the sixth transistor T6 and the anode of the organic light emitting diode OLED, and a drain electrode D7 of the seventh transistor T7 is connected to the initialization voltage line 124 and the source electrode S4 of the fourth transistor T4.

A second end Cst2 of the storage capacitor Cst is connected to the driving voltage line 172, and a cathode of the organic light emitting diode OLED is connected to a common voltage ELVSS. Hence, the organic light emitting diode OLED receives the emission current Ioled from the first transistor T1 and displays images.

An embodiment is described with reference to the pixel including seven transistors and one capacitor shown in FIG. 1, but is not necessarily limited thereto, and is applicable to pixels of various structures.

A detailed process for operating a pixel of a display device according to an embodiment will now be described.

For an initialization period, a low-level previous scan signal Sn-1 is supplied through the previous scan line 122. The fourth transistor T4 is turned on corresponding to the low-level previous scan signal Sn-1, the initialization voltage Vint is applied to the gate electrode of the first transistor T1 from the initialization voltage line 124 through the fourth transistor T4, and the first transistor T1 is initialized by the initialization voltage Vint.

For a data programming period, a low-level scan signal Sn is supplied through the scan line 121. The second transistor T2 and the third transistor T3 are turned on corresponding to the low-level scan signal Sn.

In this instance, the first transistor T1 is diode-connected by the turned-on third transistor T3, and is biased in a forward direction.

A compensation voltage (Dm+Vth, here Vth is a (−) value) generated by subtracting a threshold voltage Vth of the first transistor T1 from the data signal Dm supplied from the data line 171 is applied to the gate electrode of the first transistor T1.

The driving voltage ELVDD and the compensation voltage Dm+Vth are applied to respective ends of the storage capacitor Cst, and charges corresponding to a voltage difference between the respective ends are stored in the storage capacitor Cst. For an emission period, the emission control signal En supplied from the emission control line 123 is changed to low level from high level. The fifth transistor T5 and the sixth transistor T6 are turned on by the low-level emission control signal En.

A driving current Id following a voltage difference between the voltage at the gate electrode of the first transistor T1 and the driving voltage ELVDD is generated, and the driving current Id is supplied to the organic light emitting diode OLED through the sixth transistor T6. For the emission period, a gate-source voltage Vgs of the first transistor T1 is maintained to be (Dm+Vth)−ELVDD by the storage capacitor Cst, and according to a current-voltage relationship of the first transistor T1, the driving current Id is proportional to a square (Dm−ELVDD)2 of a subtraction of a threshold voltage from the source-gate voltage. Therefore, the driving current Id is determined in no connection with the threshold voltage Vth of the first transistor T1.

In this instance, the seventh transistor T7 receives a bypass signal BP from the bypass line 128. The bypass signal BP is a voltage at a selectable level for turning off the seventh transistor T7, and as the seventh transistor T7 receives a voltage at a transistor Off level through the gate electrode G7, the seventh transistor T7 is turned off, and some of the driving current Id is discharged through the seventh transistor T7 as a bypass current Ibp.

Therefore, in case that the driving current for displaying a black image flows, an emission current Ioled of the organic light emitting diode OLED reduced by a current amount of the bypass current Ibp passing through the seventh transistor T7 from the driving current Id has a minimum current amount that may express the black image. A contrast ratio may be improved by using the seventh transistor T7 and realizing the image with accurate black luminance.

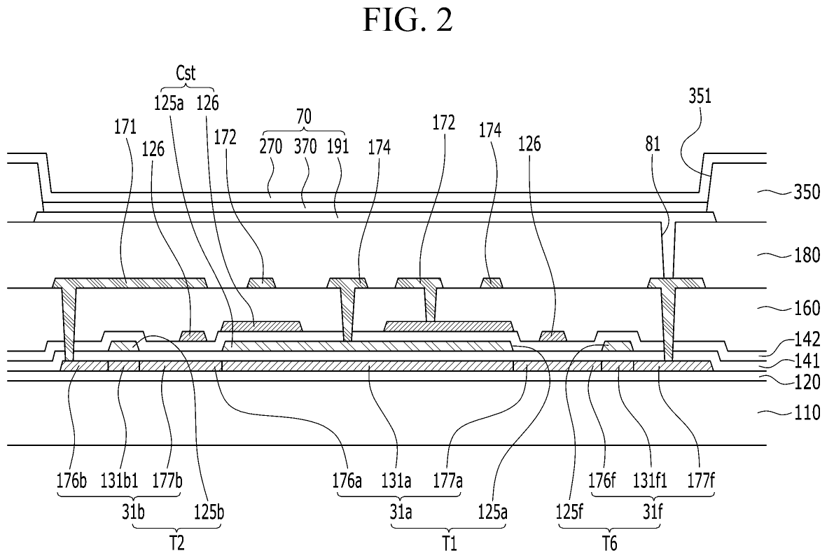

A detailed structure of a pixel of a display device shown in FIG. 1 will now be described with reference to FIG. 2 to FIG. 4 together with FIG. 1.

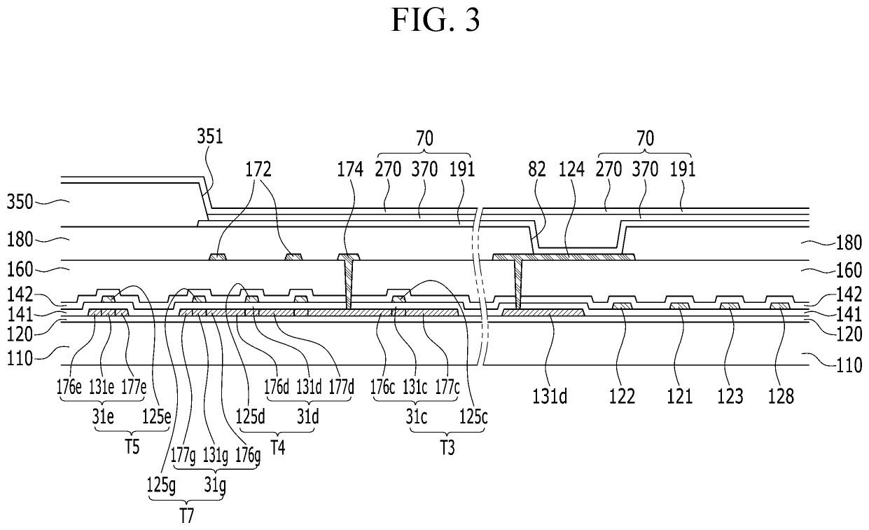

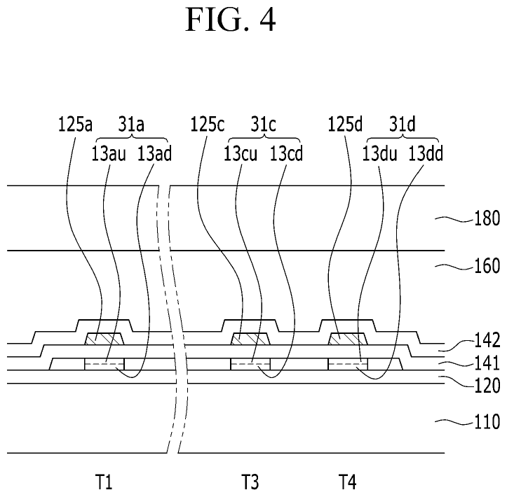

FIG. 2 shows a schematic cross-sectional view of a first transistor, a second transistor, and a sixth transistor of a display device of FIG. 1, FIG. 3 shows a schematic cross-sectional view of a third transistor, a fourth transistor, a fifth transistor, and a seventh transistor of a display device of FIG. 1, and FIG. 4 shows an enlarged schematic cross-sectional view of semiconductor layers of a first transistor, a third transistor, and a fourth transistor of a display device of FIG. 1.

As shown in FIG. 2 to FIG. 4, a buffer layer 120 may be disposed on a substrate 110. The substrate 110 may be a rigid substrate including glass. The substrate 110 may be a flexible substrate including polymers such as polyimide, polyamide, or polyethylene terephthalate. The buffer layer 120 may block impurities from the substrate 110 in case that forming a semiconductor layer, to improve characteristics of the semiconductor layer, and may planarize the surface of the substrate 110 to reduce a stress of the semiconductor layer. The buffer layer 120 may include an inorganic insulating material such as a silicon nitride (SiNₓ), a silicon oxide (SiOₓ), and a silicon oxynitride (SiOₓN_{y}). The buffer layer 120 may also include amorphous silicon.

A first semiconductor layer 31a of the first transistor T1, a second semiconductor layer 31b of the second transistor T2, a third semiconductor layer 31c of the third transistor T3, a fourth semiconductor layer 31d of the fourth transistor T4, a fifth semiconductor layer 31e of the fifth transistor T5, a sixth semiconductor layer 31f of the sixth transistor T6, and a seventh semiconductor layer 31g of the seventh transistor T7 may be disposed on the buffer layer 120.

The first semiconductor layer 31a may include a first channel region 131a overlapping a first gate electrode 125a, and a first source region 176a and a first drain region 177a disposed near respective ends of the first channel region 131a. Here, the first source region 176a and the first drain region 177a may function as a first source electrode and a first drain electrode, respectively.

Similar to the first semiconductor layer 31a, the second semiconductor layer 31b may include a second channel region 131b, a second source region 176b, and a second drain region 177b, the third semiconductor layer 31c may include a third channel region 131c, a third source region 176c, and a third drain region 177c, the fourth semiconductor layer 31d may include a fourth channel region 131d, a fourth source region 176d, and a fourth drain region 177d, the fifth semiconductor layer 31e may include a fifth channel region 131e, a fifth source region 176e, and a fifth drain region 177e, the sixth semiconductor layer 31f may include a sixth channel region 131f, a sixth source region 176f, and a sixth drain region 177f, and the seventh semiconductor layer 31g may include a seventh channel region 131g, a seventh source region 176g, and a seventh drain region 177g. Here, the second source region 176b and the second drain region 177b may function as a second source electrode and a second drain electrode, the third source region 176c and the third drain region 177c may function as a third source electrode and a third drain electrode, the fourth source region 176d and the fourth drain region 177d may function as a fourth source electrode and a fourth drain electrode, the fifth source region 176e and fifth drain region 177e may function as a fifth source electrode and a fifth drain electrode, the sixth source region 176f and the sixth drain region 177f may function as a sixth source electrode and a sixth drain electrode, and the seventh source region 176g and the seventh drain region 177g may function as a seventh source electrode and a seventh drain electrode.

As shown in FIG. 4, the first semiconductor layer 31a of the first transistor T1 may include fluorine ions (F). The first semiconductor layer 31a of the first transistor T1 may include a first lower doping layer 13ad and a first upper doping layer 13au disposed sequentially upward from the substrate 110. The concentration of the fluorine ions (F) of the first upper doping layer 13au may be greater than the concentration of the fluorine ions (F) of the first lower doping layer 13ad. The fluorine ions may have an improved interface characteristic with a layer contacting the first upper doping layer 13au, for example, the first gate insulating layer 141. Therefore, a hysteresis phenomenon may be minimized and the afterimage may be reduced.

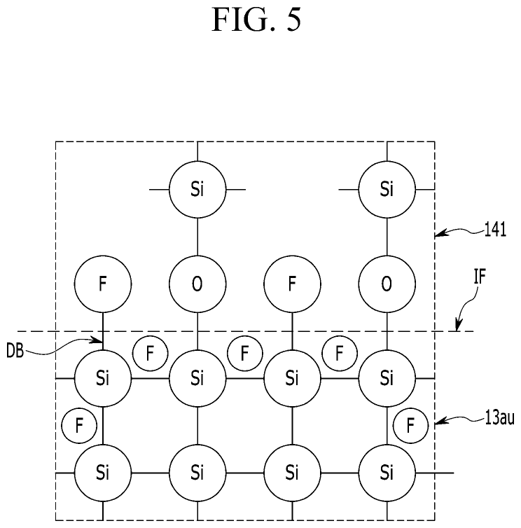

This will now be described in detail with reference to FIG. 5.

FIG. 5 shows a combined state at an interface between a first upper doping layer of a first semiconductor layer of a first transistor and a first gate insulating layer of FIG. 1.

As shown in FIG. 5, fluorine ions dispersed in the first upper doping layer 13au may be combined to a combined portion DB of arranged silicon (Si) in the first upper doping layer. For example, the fluorine ions may be combined to the fluorine ions in the first upper doping layer 13au or ions may be combined to the fluorine ions spread in the first gate insulating layer 141.

Therefore, exposure of the combined portion DB of silicon (Si) that is not combined in the first upper doping layer 13au on the interface IF may be minimized, and the silicon (Si) and the fluorine ions have a Si—F combination with high combination energy (for example, about 576.4 KJ/mol) and resultantly have an excellent reliability characteristic. For example, since the ratio of silicon (Si) constituting the Si—F combination that is adjacent to the surface of the first upper doping layer 13au that is adjacent to the interface IF increases, a stable combination may be maintained even under harsh process conditions, so the display device according to an embodiment may have an improved reliability characteristic. The exposure of the combined portion DB of silicon (Si) that is not bonded to the surface of the first upper doping layer 13au adjacent to the interface IF is minimized, thereby minimizing the phenomenon that other charges are trapped in the combined portion DB of silicon (Si) and increasing mobility of charges. Accordingly, in case that the first transistor is driven, an absolute value of the threshold voltage Vth may be lowered and the threshold voltage hysteresis corresponding to the difference between the threshold voltages of the forward and reverse directions may be reduced so the afterimage holding time may also be reduced.

As shown in FIG. 4, the third semiconductor layer 31c of the third transistor T3 may include a third lower doping layer 13cd and a third upper doping layer 13cu that are sequentially disposed upward from the substrate 110. The third lower doping layer 13cd may include doped phosphorus ions (P) and doped boron ions (B), and the third upper doping layer 13cu may include doped phosphorus ions (P) and doped boron ions (B).

The fourth semiconductor layer 31d of the fourth transistor T4 may include a fourth lower doping layer 13dd and a fourth upper doping layer 13du sequentially disposed upward from the substrate 110. The fourth lower doping layer 13dd may include doped phosphorus ions and doped boron ions, and the fourth upper doping layer 13du may include doped phosphorus ions and doped boron ions.

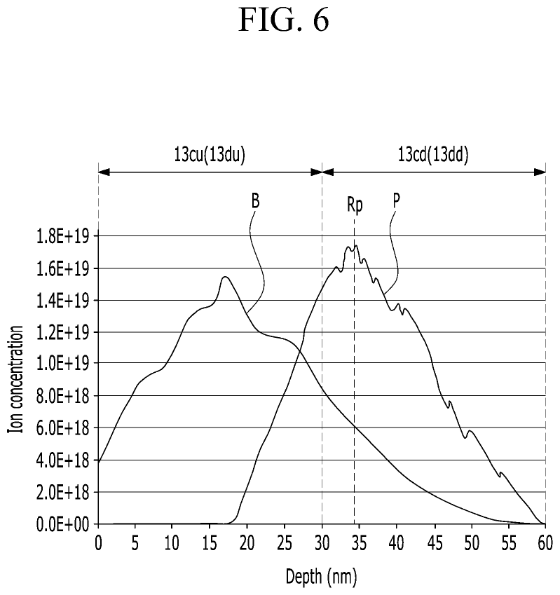

FIG. 6 shows a graph of ion concentrations with respect to depth of a third semiconductor layer 31c of a third transistor T3 or a fourth semiconductor layer 31d of a fourth transistor T4 of FIG. 4.

As shown in FIG. 6, the concentration of phosphorus ions of the third lower doping layer 13cd may be greater than the concentration of phosphorus ions of the third upper doping layer 13cu. The concentration of boron ions of the third upper doping layer 13cu may be greater than the concentration of boron ions of the third lower doping layer 13cd. In detail, a maximum point Rp of the concentration of phosphorus ions of the third semiconductor layer 31c may be disposed on the third lower doping layer 13cd. A leakage current generated by the third transistor T3 may be minimized.

The concentration of phosphorus ions of the fourth lower doping layer 13dd may be greater than the concentration of phosphorus ions of the fourth upper doping layer 13du. The concentration of boron ions of the fourth upper doping layer 13du may be greater than the concentration of boron ions of the fourth lower doping layer 13dd. In detail, the maximum point Rp of the concentration of phosphorus ions of the fourth semiconductor layer 31d may be disposed on the fourth lower doping layer 13dd. The leakage current generated to the fourth transistor T4 may be minimized.

As such, by increasing the concentration of phosphorus ions of the third lower doping layer 13cd of the third semiconductor layer 31c of the third transistor T3 and the concentration of phosphorus ions of the fourth lower doping layer 13dd of the fourth semiconductor layer 31d of the fourth transistor T4, which affect the leakage current, the leakage current may be minimized.

In case that a low frequency driving of about 60 Hz or less is performed to reduce power consumption, flickers such as flickering or blinking of the screen is likely to occur due to the leakage current, but in an embodiment, the generation of flickers may be controlled by minimizing the leakage current in case that performing the low frequency driving.

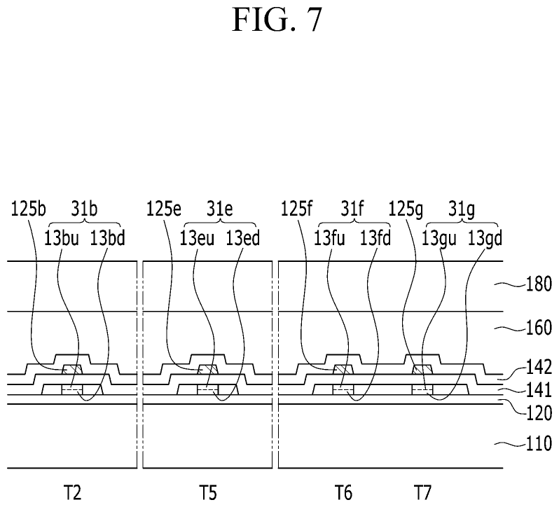

FIG. 7 shows enlarged schematic cross-sectional views of semiconductor layers of a second transistor, a fifth transistor, a sixth transistor, and a seventh transistor of a display device of FIG. 1.

As shown in FIG. 7, the concentration of phosphorus ions of the second lower doping layer 13bd of the second semiconductor layer 31b may be greater than the concentration of phosphorus ions of the second upper doping layer 13bu. By way of example, the maximum point Rp of the concentration of phosphorus ions of the second semiconductor layer 31b may be disposed on the second lower doping layer 13bd. Similarly, the concentration of phosphorus ions of the fifth lower doping layer 13ed of the fifth semiconductor layer 31e may be greater than the concentration of phosphorus ions of the fifth upper doping layer 13eu, the concentration of phosphorus ions of the sixth lower doping layer 13fd of the sixth semiconductor layer 31f may be greater than the concentration of phosphorus ions of the sixth upper doping layer 13fu, and the concentration of phosphorus ions of the seventh lower doping layer 13gd of the seventh semiconductor layer 31g may be greater than the concentration of phosphorus ions of the seventh upper doping layer 13gu. Therefore, the leakage current generated by the second transistor T2, the fifth transistor T5, the sixth transistor T6, and the seventh transistor T7 may be minimized.

In an embodiment, the semiconductor layer of the second transistor T2, the fifth transistor T5, the sixth transistor T6, and the seventh transistor T7 is formed to have the same structure or substantially the same structure as the semiconductor layer of the third transistor and fourth transistors, but they are not limited thereto, the semiconductor layer of the second transistor T2, the fifth transistor T5, the sixth transistor T6, and the seventh transistor T7 may be doped with boron ions as an embodiment.

A first gate insulating layer 141 for covering the first semiconductor layer 31a, the second semiconductor layer 31b, the third semiconductor layer 31c, the fourth semiconductor layer 31d, the fifth semiconductor layer 31e, the sixth semiconductor layer 31f, and the seventh semiconductor layer 31g may be disposed on the buffer layer 120. The first gate insulating layer 141 may include an inorganic insulating material such as a silicon oxide, a silicon nitride, or a silicon oxynitride, and may be a single layer or a multilayer.

A first gate conductive layer including a scan line 121 including a second gate electrode 125b and a third gate electrode 125c, a previous scan line 122 including a fourth gate electrode 125d, an emission control line 123 including a fifth gate electrode 125e and a sixth gate electrode 125f, and a bypass line 128 including a first gate electrode (or a first storage capacitive plate) 125a and a seventh gate electrode 125g may be disposed on the first gate insulating layer 141. The first gate conductive layer may include molybdenum (Mo), aluminum (Al), copper (Cu), titanium (Ti), and tungsten (W), and may be a single layer or a multilayer.

A second gate insulating layer 142 may be disposed on the first gate conductive layer. The second gate insulating layer 142 may include an inorganic insulating material such as a silicon oxide, a silicon nitride, or a silicon oxynitride, and may be a single layer or a multilayer.

A second gate conductive layer including a second storage capacitive plate 126 overlapping the first storage capacitive plates 125a may be disposed on the second gate insulating layer 142. The first storage capacitive plates 125a and the second storage capacitive plates 126 overlap each other and form the storage capacitor Cst. The second gate conductive layer may include molybdenum (Mo), aluminum (Al), copper (Cu), titanium (Ti), and tungsten (W), and may be a single layer or a multilayer.

An interlayer insulating layer 160 may be disposed on the second gate conductive layer. The interlayer insulating layer 160 may include an inorganic insulating material such as a silicon oxide, a silicon nitride, or a silicon oxynitride, and may be a single layer or a multilayer. In case that the interlayer insulating layer 160 has dual layers, a lower layer may include a silicon nitride, and an upper layer may include a silicon oxide.

A data conductive layer including a data line 171, a driving voltage line 172, a connecting member 174, and an initialization voltage line 124 may be disposed on the interlayer insulating layer 160. The data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may be a single layer or a multilayer. For example, the data conductive layer may have triple layers of titanium (Ti)/aluminum (Al)/titanium (Ti), or may have dual layers of titanium (Ti)/copper (Cu).

A protection layer 180 for covering the data conductive layer may be disposed on the interlayer insulating layer 160. The protection layer 180 may include an organic insulating material such as a general-purpose polymer including poly(methyl methacrylate) and polystyrene, a polymer derivative having a phenol-based group, an acryl-based polymer, an imide-based polymer (for example, a polyimide), or a siloxane-based polymer.

A pixel electrode 191 may be disposed on the protection layer 180. The sixth transistor T6 is connected to the pixel electrode 191 through a contact hole 81 formed in the protection layer 180, and the initialization voltage line 124 is connected to the pixel electrode 191 through a contact hole 82 formed in the protection layer 180. The pixel electrode 191 may include a metal such as lithium (Li), calcium (Ca), aluminum (Al), silver (Ag), magnesium (Mg), or gold (Au). The pixel electrode 191 may be a multilayer, for example, it may have triple layers of ITO/silver (Ag)/ITO.

A cell barrier 350 may be disposed on an edge of the pixel electrode 191 and the protection layer 180, and the cell barrier 350 has a cell barrier opening 351 overlapping the pixel electrode 191. The cell barrier 350 may be made of polyacrylate resin and a polyimide resin or a silica-based inorganic material.

An organic emission layer 370 may be disposed on the pixel electrode 191 overlapping the cell barrier opening 351, and a common electrode 270 may be disposed on the organic emission layer 370. As described, the organic light emitting diode 70 including a pixel electrode 191, an organic emission layer 370, and a common electrode 270 may be formed.

The pixel electrode 191 is an anode that is a hole injection electrode, and the common electrode 270 is a cathode that is an electron injection electrode. However, the embodiment is not limited thereto, and the pixel electrode 191 may be a cathode and the common electrode 270 may be an anode according to a method for driving a display device. Holes and electrons are injected into the organic emission layer 370 from the pixel electrode 191 and the common electrode 270, respectively, and light emission occurs in case that the exciton combined with the injected holes and electrons falls from the excited state to the ground state.

The organic emission layer 370 may be made of a low-molecule organic material or a polymer organic material such as PEDOT (poly 3,4-ethylenedioxythiophene). The organic emission layer 370 may be a multilayer including at least one of an emission layer, a hole injection layer (HIL), a hole transporting layer (HTL), an electron transporting layer (ETL), and an electron injection layer (EIL). In case that all of these are included, the hole injection layer is disposed on the pixel electrode 191 which is a positive electrode, and the hole transport layer, the light emitting layer, the electron transport layer, and an electron injection layer may be sequentially stacked each other thereon.

The organic emission layer 370 may include a red organic emission layer emitting a red color, a green organic emission layer emitting a green color, and a blue organic emission layer emitting a blue color, and the red organic emission layer, the green organic emission layer, and the blue organic emission layer are formed on red pixels, green pixels, and blue pixels, respectively, to realize color images.

Regarding the organic emission layer 370, the red organic emission layer, the green organic emission layer, and the blue organic emission layer may be stacked on the red pixel, the green pixel, and the blue pixel altogether each other, and a red color filter, a green color filter, and a blue color filter may be formed for the respective pixels to realize color images. For another example, a white organic emission layer for emitting white light may be formed on the red pixel, the green pixel, and the blue pixel, and a red color filter, a green color filter and a blue color filter may be formed for the respective pixels to realize the color images. In case that the color images are realized by using the white organic emission layer and the color filters, there is no need to use a deposition mask for depositing the red organic emission layer, the green organic emission layer, and the blue organic emission layer on the individual pixels, for example, the red pixel, the green pixel, and the blue pixel.

The white organic emission layer described in another example may be formed of one organic emission layer, and may include a configuration in which organic emission layers may be stacked each other to emit white light. For example, it may include a combination of at least one yellow organic emission layer and at least one blue organic emission layer enables white emission, and a combination of at least one cyan organic emission layer and at least one red organic emission layer enables white emission, and a combination of at least one magenta organic emission layer and at least one green organic emission layer enables white emission.

An encapsulation member (not shown) for protecting the organic light emitting diode 70 may be disposed on the common electrode 270, and the encapsulation member may be sealed to the substrate 110 by a sealant, and may include various materials such as glass, quartz, ceramic, plastic, or a metal. A thin film encapsulation layer formed by depositing an inorganic film and an organic film on the common electrode 270 without using a sealant may be disposed.

A method for manufacturing a display device according to the embodiment will be described in detail with reference to drawings below.

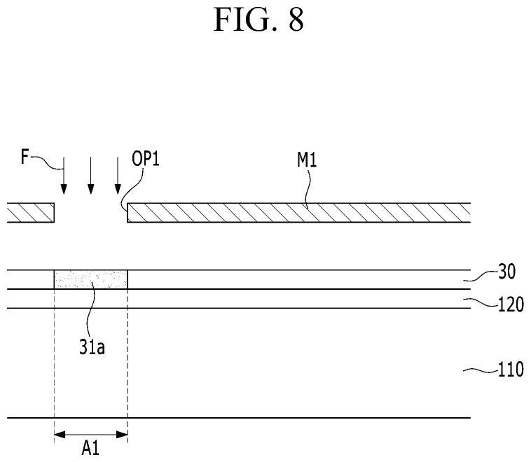

FIG. 8 to FIG. 10 show sequential schematic cross-sectional views of a method for manufacturing a display device according to an embodiment, showing enlarged schematic cross-sectional views of a first transistor, a second transistor, and a fourth transistor of a display device of FIG. 1.

As shown in FIG. 8, a buffer layer 120 is formed on the substrate 110, and a semiconductor layer 30 is formed on the buffer layer 120. The semiconductor layer 30 may 30 maybe formed into first to seventh semiconductor layers 31a, 31b, 31c, 31d, 31e, 31f, and 31g through subsequent processes, and in an embodiment, and for convenience of explanation, the first semiconductor layer 31a of the first transistor T1, the third semiconductor layer 31c of the third transistor T3, and the fourth semiconductor layer 31d of fourth transistor T4 will be described.

The first semiconductor layer 31a is formed by doping fluorine ions in the first region A1 of the semiconductor layer 30 using the first mask M1. To achieve this, the opening OP1 of the first mask M1 is disposed correspondingly to first region A1 so that fluorine ions may be doped in the first region A1. Here, the fluorine ions are accelerated by a range of about 3 to about 15 KeV, and a range of about 1×10¹¹ to about 1×10¹² cm⁻² may be doped. At a voltage that is lower than about 3 KeV, it is difficult for fluorine ions to be accelerated, and at a voltage that is higher than about 15 KeV, there is no change in the doped depth of fluorine ions.

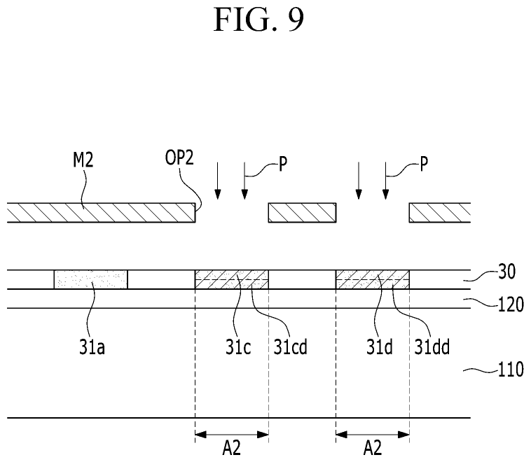

As shown in FIG. 9, phosphorus ions are doped in the second region A2 of the semiconductor layer to form a third semiconductor layer 31c and a fourth semiconductor layer 31d by using a second mask M2. For this purpose, an opening OP2 of the second mask M2 is disposed corresponding to the second region A2 so the phosphorus ions may be doped in the second region A2. At this time, the phosphorus ions may be doped in the lower region of the second region A2 to form lower doping layers 13cd and 13dd.

The first semiconductor layer 31a, the third semiconductor layer 31c, and the fourth semiconductor layer 31d are crystallized. For example, the first semiconductor layer 31a may be crystallized after forming the first semiconductor layer 31a by doping fluorine ions in the first region A1. The third semiconductor layer 31c and the fourth semiconductor layer 31d are formed by doping phosphorus ions in the second region A2, and the third semiconductor layer 31c and the fourth semiconductor layer 31d are crystallized.

As the phosphorus ions have a large atomic weight, it is easy to cause damage to the semiconductor layer during doping phosphorus ions, so high heat energy is required to remove the damage after doping the phosphorus ions. The crystallization process is performed after the high heat energy is applied to the third semiconductor layer 31c and the fourth semiconductor layer 31d so damages to the crystal silicon of the third semiconductor layer 31c and the fourth semiconductor layer 31d due to the high heat energy may be minimized. For example, in case that doping the phosphorus ions after the crystallization process is performed, the crystal silicon may be damaged by the applied high heat energy, but as in an embodiment, in case that performing the crystallization process after doping the phosphorus ions may minimize the damage of crystal silicon.

In an embodiment, laser crystallization like ELA is performed, but is not limited thereto and various crystallization methods may be used.

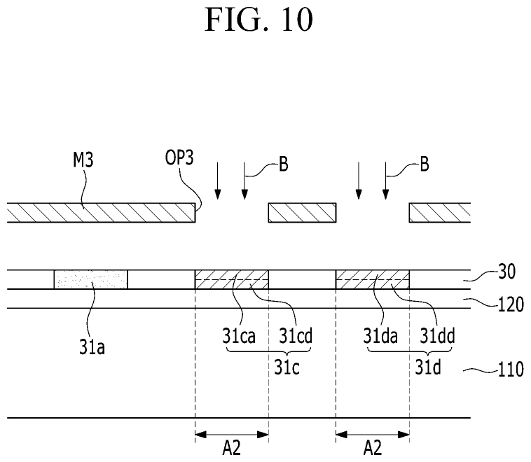

As shown in FIG. 10, upper doping layers 13cu and 13du are formed by doping boron ions on upper portions of the third semiconductor layer 31c and the fourth semiconductor layer 31d using a third mask M3. To this end, the boron ions may be doped in the second region A2 by disposing an opening OP3 of the third mask M3 in the second region A2. As described, boron ions may be doped into the third semiconductor layer 31c and the fourth semiconductor layer 31d after crystallizing the third semiconductor layer 31c and the fourth semiconductor layer 31d.

At this time, an acceleration voltage applied to the phosphorus ions may be greater than an acceleration voltage applied to the boron ions. For example, the phosphorus ions are accelerated by a range of about 10 to about 40 KeV and a doping concentration of the phosphorous ions is in a range of about 1×10¹¹ to about 1×10¹² cm⁻², and the boron ions are accelerated by a range of about 3 to about 15 KeV and a doping concentration of the boron ions is in a range of about 1×10¹¹ to about 1×10¹² cm⁻². It is difficult to accelerate the phosphorus ions at a voltage that is lower than about 10 KeV, and the doped depth of phosphorus ions does not change at a voltage that is higher than about 40 KeV. It is difficult to accelerate the boron ions at a voltage that is lower than about 3 KeV, and there is no change in the doped depth of the boron ions at a voltage that is higher than about 15 KeV.

Therefore, the concentration of phosphorus ions of the third lower doping layer 13cd may be greater than the concentration of phosphorus ions of the third upper doping layer 13cu, and the concentration of boron ions of the third upper doping layer 13cu may be greater than the concentration of boron ions of the third lower doping layer 13cd.

The concentration of phosphorus ions of the fourth lower doping layer 13dd may be greater than the concentration of phosphorus ions of the fourth upper doping layer 13du, and the concentration of boron ions of the fourth upper doping layer 13du may be greater than the concentration of boron ions of the fourth lower doping layer 13dd.

As shown in FIG. 4 and FIG. 7, a first gate insulating layer 141 for covering the first semiconductor layer 31a, the second semiconductor layer 31b, the third semiconductor layer 31c, the fourth semiconductor layer 31d, the fifth semiconductor layer 31e, the sixth semiconductor layer 31f, and the seventh semiconductor layer 31g may be formed on the buffer layer 120. A first gate conductive layer including the first gate electrode 125a, the second gate electrode 125b, the third gate electrode 125c, the fourth gate electrode 125d, the fifth gate electrode 125e, the sixth gate electrode 125f, and the seventh gate electrode 125g is formed on the first gate insulating layer 141. A second gate insulating layer 142 is formed on the first gate conductive layer. As shown in FIG. 2, a second gate conductive layer including the second storage capacitive plate 126 is formed on the second gate insulating layer 142, and an interlayer insulating layer 160 is formed on the gate conductive layer. As shown in FIG. 2 and FIG. 3, a data conductive layer including the data line 171, the driving voltage line 172, the connecting member 174, and the initialization voltage line 124 is formed on the interlayer insulating layer 160. A protection layer 180 for covering the data conductive layer is formed on the interlayer insulating layer 160.

While this disclosure has been described in connection with what is considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A display device comprising:
a light-emitting device;
a first transistor that outputs a driving current applied to the light-emitting device;
a second transistor that transmits a data voltage to a first electrode of the first transistor; and
a third transistor electrically connected to a second electrode and a gate electrode of the first transistor, wherein
a first semiconductor layer of the first transistor includes fluorine ions,
a third semiconductor layer of the third transistor includes a third lower doping layer and a third upper doping layer sequentially disposed,
a concentration of phosphorus ions of the third lower doping layer is greater than a concentration of phosphorus ions of the third upper doping layer, and
a concentration of boron ions of the third upper doping layer is greater than a concentration of boron ions of the third lower doping layer.

2. The display device of claim 1, wherein a maximum point of a concentration of phosphorus ions of the third semiconductor layer is disposed on the third lower doping layer.

3. The display device of claim 1, further comprising:
a fourth transistor that transmits an initialization voltage to a gate electrode of the first transistor, wherein
a fourth semiconductor layer of the fourth transistor includes a fourth lower doping layer and a fourth upper doping layer sequentially disposed,
a concentration of phosphorus ions of the fourth lower doping layer is greater than a concentration of phosphorus ions of the fourth upper doping layer, and
a concentration of boron ions of the fourth upper doping layer is greater than a concentration of boron ions of the fourth lower doping layer.

4. The display device of claim 3, wherein a maximum point of the concentration of phosphorus ions of the fourth semiconductor layer is disposed on the fourth lower doping layer.

5. The display device of claim 3, further comprising:
a fifth transistor that transmits a driving voltage to a first electrode of the first transistor;
a sixth transistor that transmits the driving voltage to the light-emitting device from the fifth transistor; and
a seventh transistor that electrically connects a first electrode of the fourth transistor to a first electrode of the sixth transistor.

6. The display device of claim 5, wherein
a fifth semiconductor layer of the fifth transistor includes a fifth lower doping layer and a fifth upper doping layer sequentially disposed,
a concentration of phosphorus ions of the fifth lower doping layer is greater than a concentration of phosphorus ions of the fifth upper doping layer,
a concentration of boron ions of the fifth upper doping layer is greater than a concentration of boron ions of the fifth lower doping layer,
a sixth semiconductor layer of the sixth transistor includes a sixth lower doping layer and a sixth upper doping layer sequentially disposed,
a concentration of phosphorus ions of the sixth lower doping layer is greater than a concentration of phosphorus ions of the sixth upper doping layer,
a concentration of boron ions of the sixth upper doping layer is greater than a concentration of boron ions of the sixth lower doping layer,
a seventh semiconductor layer of the seventh transistor includes a seventh lower doping layer and a seventh upper doping layer sequentially disposed,
a concentration of phosphorus ions of the seventh lower doping layer is greater than a concentration of phosphorus ions of the seventh upper doping layer, and
a concentration of boron ions of the seventh upper doping layer is greater than a concentration of boron ions of the seventh lower doping layer.

7. The display device of claim 5, wherein
a fifth semiconductor layer of the fifth transistor includes boron ions,
a sixth semiconductor layer of the sixth transistor includes boron ions, and
a seventh semiconductor layer of the seventh transistor includes boron ions.

8. The display device of claim 3, wherein the third transistor and the fourth transistor are driven at a low frequency substantially equal to or less than about 60 Hz.

9. A method for manufacturing a display device comprising:
forming a semiconductor layer on a substrate;
forming a first semiconductor layer of a first transistor that outputs a driving current applied to a light-emitting device by doping fluorine ions in a first region of the semiconductor layer;
forming a third semiconductor layer of a third transistor electrically connected to a second electrode and a gate electrode of the first transistor by doping phosphorus ions to a lower portion of a second region of the semiconductor layer;
crystallizing the first semiconductor layer and the third semiconductor layer; and
doping boron ions on an upper portion of the third semiconductor layer.

10. The method of claim 9, wherein
the third semiconductor layer includes a third lower doping layer and a third upper doping layer sequentially disposed,
a concentration of phosphorus ions of the third lower doping layer is greater than a concentration of phosphorus ions of the third upper doping layer, and
a concentration of boron ions of the third upper doping layer is greater than a concentration of boron ions of the third lower doping layer.

11. The method of claim 10, wherein
a fourth semiconductor layer of a fourth transistor that transmits an initialization voltage to a gate electrode of the first transistor is formed in the second region,
the fourth semiconductor layer includes a fourth lower doping layer and a fourth upper doping layer sequentially disposed,
a concentration of phosphorus ions of the fourth lower doping layer is greater than a concentration of phosphorus ions of the fourth upper doping layer, and
a concentration of boron ions of the fourth upper doping layer is greater than a concentration of boron ions of the fourth lower doping layer.

12. The method of claim 10, wherein
the first semiconductor layer is crystallized after the fluorine ions are doped on the first semiconductor layer.

13. The method of claim 10, wherein
the third semiconductor layer and the fourth semiconductor layer are crystallized after the phosphorus ions are doped on the third semiconductor layer and the fourth semiconductor layer.

14. The method of claim 10, wherein
the boron ions are doped on the third semiconductor layer and the fourth semiconductor layer after the third semiconductor layer and the fourth semiconductor layer are crystallized.

15. The method of claim 10, wherein an acceleration voltage applied to the phosphorus ions is greater than an acceleration voltage applied to the boron ions.

16. The method of claim 15, wherein
the fluorine ions are accelerated by a range of about 3 to about 15 KeV, and
a doping concentration of the fluorine ions is in a range of about 1×10¹¹ to about 1×10¹² cm⁻².

17. The method of claim 15, wherein
the phosphorus ions are accelerated by a range of about 10 to about 40 KeV, and
a doping concentration of the phosphorus ions is in a range of about 1×10¹¹ to about 1×10¹² cm⁻².

18. The method of claim 15, wherein
the boron ions are accelerated by a range of about 3 to about 15 KeV, and
a doping concentration of the boron ions is in a range of about 1×10¹¹ to about 1×10¹² cm⁻².

19. A method for manufacturing a display device comprising:
forming a semiconductor layer on a substrate;
forming a first semiconductor layer by doping fluorine ions in a first region of the semiconductor layer by a first mask, and blocking the doping of fluorine ions in a second region of the semiconductor layer;
forming a third semiconductor layer and a fourth semiconductor layer by doping phosphorus ions in a second region of the semiconductor layer by a second mask, and blocking the doping of phosphorus ions in a first region of the semiconductor layer;
crystallizing the first semiconductor layer, the third semiconductor layer, and the fourth semiconductor layer; and
doping boron ions on the third semiconductor layer and the fourth semiconductor layer by a third mask, and blocking the doping of boron ions on the first semiconductor layer,
wherein an acceleration voltage applied to the phosphorus ions is greater than an acceleration voltage applied to the boron ions.

20. The method of claim 19, wherein
fluorine ions are formed on an upper portion of the first semiconductor layer, and
a maximum point of a concentration of phosphorus ions of the third semiconductor layer is disposed on a lower portion of the third semiconductor layer, and a maximum point of a concentration of phosphorus ions of the fourth semiconductor layer is disposed on a lower portion of the fourth semiconductor layer.
